(19) United States
(12) Patent Application Publication
(10) Pub. No.: US 2008/0216740 A1
(43) Pub. Date: Sep. 11, 2008

(54) Resist coating method and apparatus

(75) Inventor: Nobuaki Hoshi, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/073,335

(22) Filed: Mar. 4, 2008

(30) Foreign Application Priority Data
Mar. 8, 2007 (JP) 2007-059090

(51) Int. Cl. B05C 11/00; H01L 21/30

(52) U.S. Cl. 118/696; 438/758; 257/E21.211

(57) ABSTRACT

A resist coating method includes a dummy dispensation step for discharging a resist onto a semiconductor substrate in response to a dummy discharge signal, a pre-wet step for applying and then drying a pre-wet solvent on the semiconductor substrate, and a resist coating step for applying the resist onto the semiconductor substrate in response to a resist discharge signal. The resist discharge signal is output at a timing that precedes a predetermined dry time being elapsed by a delay time, which is calculated between the timing for outputting the dummy discharge signal and the timing for actually discharging the resist, thus normally maintaining the predetermined dry time constant. This makes it possible to stably produce pre-wet effects, to improve the uniformity regarding the thickness of a resist film formed on the semiconductor substrate, and to reduce dispersion regarding pre-wet effects between resist coating apparatuses.

### BACKGROUND OF THE INVENTION

1. Field of the Invention

The present invention relates to methods and apparatuses for coating semiconductor substrates with resists, wherein pre-wet solvents are applied to semiconductor substrates in advance and are then dried in prescribed periods of time.

The present application claims priority on Japanese Patent Application No. 2007-59090, the content of which is incorporated herein by reference.

2. Description of the Related Art

Recently, resist coating apparatuses are arranged in parallel with each other so as to improve throughputs in resist coatings. It is required to uniform thicknesses of resists among resist coating apparatuses for applying resists to semiconductor substrates (or wafers). As a method for improving uniformity regarding thicknesses of resists, pre-wet solvents are applied to semiconductor substrates (or wafers) before the formation of resists in advance. This technology is disclosed in various documents such as Patent documents 1 to 3, wherein resists may spread widely over semiconductor substrates by way of application of pre-wet solvents.

Patent document 1: Japanese Unexamined Patent Application Publication No. 2002-134399.

Patent document 2: Japanese Unexamined Patent Application Publication No. 2002-175966.

Patent document 3: Japanese Unexamined Patent Application Publication No. 2003-145017.

However, the foregoing method regarding application of pre-wet solvents may not be capable of stably producing pre-wet effects when resists are spread over semiconductor substrates; hence, it is very difficult to sufficiently improve the uniformity regarding the thicknesses of resists. In particular, a resist coating is realized using a plurality of resist coating apparatuses in parallel, which may increase dispersions regarding pre-wet effects among the resist coating apparatuses.

### SUMMARY OF THE INVENTION

It is an object of the present invention to provide a resist coating method for applying a pre-wet solvent onto a semiconductor substrate before being applied with a resist, wherein it can stably produce a pre-wet effect, it can improve uniformity regarding the thickness of the resist, and it can reduce dispersion regarding pre-wet effects among a plurality of resist coating apparatuses.

It is another object of the present invention to provide a resist coating apparatus for applying a pre-wet solvent onto a semiconductor substrate before being applied with a resist, wherein it can stably produce a pre-wet effect, it can improve uniformity regarding the thickness of the resist, and it can reduce dispersion regarding pre-wet effects among a plurality of resist coating apparatuses.

Studies have been performed to solve the foregoing problems by paying attention to the relationship between dispersions of dry times for pre-wet solvents applied to semiconductor substrates (or wafers) and dispersions of pre-wet effects, wherein they are concluded in such a way that, by maintaining constant dry times for pre-wet solvents, it is possible to stably produce desired pre-wet effects and to adequately improve the uniformity regarding the thicknesses of resist films formed on semiconductor substrates.

In addition, further studies have been performed so as to conclude that dispersions of dry times for pre-wet solvents greatly depend upon time differences between the signaling time for outputting a discharge signal by a controller and the timing for actually discharging a resist on the semiconductor substrate by a resist nozzle.

Results of studies will be described with reference to FIGS. 5 and 6.

FIG. 5 shows a basic time sequence for a resist coating step, wherein the vertical axis represents various parameters regarding the resist coating, and the horizontal axis represents time. First, at time T5, a solvent nozzle starts discharging a pre-wet solvent onto a semiconductor substrate, which is presently stopped in rotation. At time T6, the solvent nozzle stops applying the pre-wet solvent onto the semiconductor substrate, and at the same time, the semiconductor substrate is controlled to start rotating so as to start performing a dry process of the pre-wet solvent, in which the pre-wet solvent is spread on the overall surface of the semiconductor substrate. At time T7 upon a lapse of a predetermined dry time (i.e., T7−T6), an air-operate valve and a resist pump are activated so as to apply a resist onto the semiconductor substrate. After completion of coating of the resist, the dry process of the pre-wet solvent is automatically completed. Thereafter, the semiconductor substrate continues to rotate so as to form a resist film having a desired thickness on the semiconductor substrate.

FIG. 6 shows an actual time sequence with regard to the resist coating, which is actually performed in accordance with the basic time sequence of FIG. 5. Detailed examination of the actual time sequence indicates that, even when a resist discharge signal is output at time T7 at which the predetermined dry time elapses from time T6, the resist is not actually applied to the semiconductor substrate simultaneously with the resist discharge signal, wherein the resist is actually applied to the semiconductor substrate at time T8, which is delayed from time T7 by a certain delay time. Since the dry process is continued until the resist is applied to the semiconductor substrate, the dry process must be extended for a longer time, which exceeds the predetermined dry time (i.e., T7−T6) by the delay time (i.e., T8−T7). This causes an excessively dried condition so as not to stably produce a pre-wet effect; hence, this degrades the uniformity regarding the thickness of the resist film formed on the semiconductor substrate. The delay time may occur due to aged variations of the apparatus, in other words, due to operational errors caused by deterioration of parts and adhesion of resists.

The present invention is created in consideration of the aforementioned results of the studies.

In a first aspect of the present invention, a resist coating method includes a dummy dispensation step for discharging a resist onto a semiconductor substrate in response to a dummy discharge signal and for calculating a delay time between the timing for issuing the dummy discharge signal and the timing for discharging the resist, a pre-wet step for applying a pre-wet solvent onto the semiconductor substrate and for performing a dry process on the pre-wet solvent for a predetermined dry time, and a resist coating step, subsequent to the pre-wet step, for discharging the resist in response to a resist discharge signal so as to apply the resist onto the semiconductor substrate, wherein the resist is applied to the semiconductor substrate in the resist coating step in such a way that the resist discharge signal is output at a timing that precedes the predetermined dry time being elapsed by the delay time, thus normally maintaining the predetermined delay time constant.

In the aforementioned resist coating method, the resist discharge signal is output at a timing that precedes the predetermined dry time being elapsed by the delay time; hence, it is possible to precisely match the timing for discharging the resist with the predetermined dry time being elapsed; thus, it is possible to normally maintain a constant dry time while avoiding negative influences due to the delay time.

In addition, the dry process is started at the timing which is delayed from the timing for completing the application of the pre-wet solvent by the delay time, wherein the delay time adapted to the start timing of the dry process is canceled by the delay time between the timing for outputting the resist discharge signal and the timing for actually discharging the resist, thus normally maintaining the constant dry time of the pre-wet solvent.

Furthermore, the resist coating method is realized using a plurality of resist coating apparatuses, among which the dry time of the pre-wet solvent is normally maintained constant, thus reducing dispersion regarding the thickness of a resist film formed on the semiconductor substrate therebetween.

In the resist coating method, a video device is used to detect the timing for actually discharging the resist, based on which the delay time is calculated. The resist coating step is realized using an air-operate valve and a resist pump, wherein the discharge condition adjustment is performed between the operation timing of the air-operate valve and the operation timing of the resist pump before the dummy dispensation step.

In a second aspect of the present invention, a resist coating apparatus includes a pre-wet means for applying a pre-wet solvent onto a semiconductor substrate and for performing a dry process on the pre-wet solvent for a predetermined dry time, a resist coating means for discharging a resist onto the semiconductor substrate, and a controller for outputting a dummy discharge signal to the resist coating means to start discharging the resist, for calculating a delay time corresponding to a time difference between the timing for outputting the dummy discharge signal and the timing for actually discharging the resist, and for outputting a resist discharge signal to the resist coating means at a timing that precedes the predetermined dry time being elapsed by the delay time, thus discharging the resist to be applied onto the semiconductor substrate.

In the above, the controller is equipped with a video device for detecting the timing for actually discharging the resist, based on which the controller calculates the delay time.

According to the present invention, the dry time of the pre-wet solvent is maintained constant irrespective of the delay time that is required for applying the resist onto the semiconductor substrate after completion of the dry process of the pre-wet solvent. Thus, it is possible to stably produce a pre-wet effect when the resist is spread over the semiconductor substrate, to stabilize the uniformity regarding the thickness of the resist film formed on the semiconductor substrate, and to reduce dispersion of pre-wet effects between resist coating apparatuses.

### BRIEF DESCRIPTION OF THE DRAWINGS

These and other objects, aspects, and embodiments of the present invention will be described in more detail with reference to the following drawings, in which:

FIG. 1 is an illustration showing a resist coating apparatus in accordance with a preferred embodiment of the present invention;

FIG. 2 is a graph showing examples of operation timings regarding an air-operate valve and a resist pump before discharge condition adjustment;

FIG. 3 is a graph showing example of operation timings regarding the air-operate valve and the resist pump after the discharge condition adjustment;

FIG. 4 is a flowchart for explaining a resist coating method in accordance with the preferred embodiment of the present invention;

FIG. 5 is a graph showing a basic time sequence for explaining a resist coating step;

FIG. 6 is a graph showing an actual time sequence for explaining the resist coating step;

FIG. 7 is a graph showing a time sequence for explaining the resist coating step in connection with a first example; and

FIG. 8 is a graph showing a time sequence for explaining a resist coating step in connection with a second example.

### DESCRIPTION OF THE PREFERRED EMBODIMENT

The present invention will be described in further detail by way of examples with reference to the accompanying drawings.

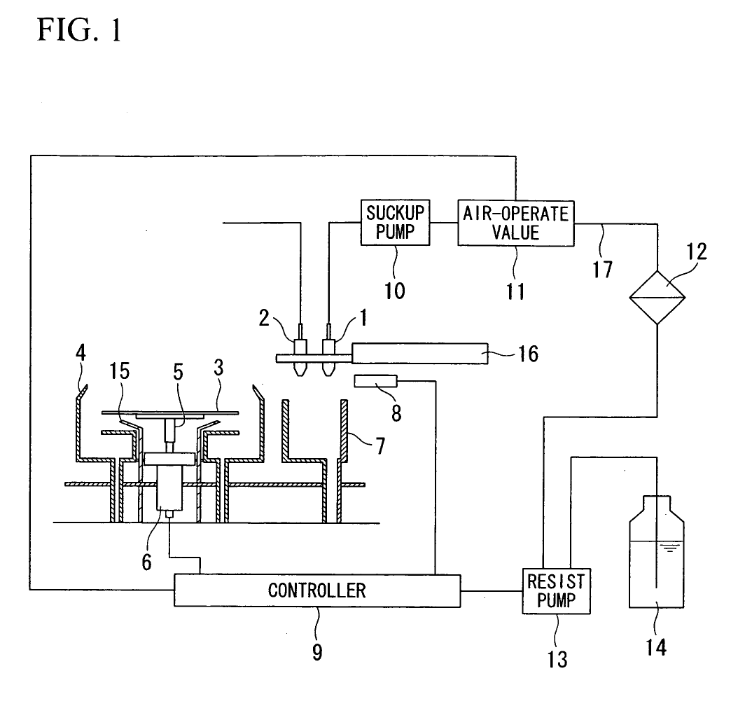

A resist coating apparatus and a resist coating method according to a preferred embodiment of the present invention will be described with reference to FIGS. 1 to 4.

### 1. RESIST COATING APPARATUS

FIG. 1 is an illustration diagrammatically showing a resist coating apparatus in accordance with the preferred embodiment of the present invention, wherein reference numeral 1 designates a resist nozzle for discharging a resist. The resist nozzle 1 is supported by a nozzle arm 16, which moves the resist nozzle 1 to a prescribed position. The resist coating apparatus of FIG. 1 is equipped with a suckup valve 10, an air-operate valve 11, a filter 12, a resist pump 13, and a resist bottle 14, all of which are interconnected together via a supply pipe 17. The air-operate valve 11 is opened or closed in response to a dummy discharge signal or a resist discharge signal output from a controller 9. The resist pump 13 forwards a resist under a prescribed pressure in response to the dummy discharge signal or the resist discharge signal output from the controller 9.

In FIG. 1, reference numeral 2 designates a solvent nozzle for discharging a pre-wet solvent. The solvent nozzle 2 is paired with the resist nozzle 1 and is supported by the nozzle arm 16, which moves the solvent nozzle 2 to a prescribed position. The resist coating apparatus of FIG. 1 is also equipped with valves and pumps (both not shown) for supplying the pre-wet solvent to the solvent nozzle 2.

In FIG. 1, reference numeral 3 designates a semiconductor substrate; reference numeral 5 designates a spin-chuck for supporting the semiconductor substrate 3; and reference numeral 6 designates a spin-motor. The spin-motor 6 rotates the semiconductor substrate 3 mounted on the spin-chuck 5, wherein the rotating speed and rotating time thereof are controlled by the controller 9. In the present embodiment, the spin-chuck 5 and the spin-motor 6 serve as a drying means for drying the pre-wet solvent or resist supplied onto the semiconductor substrate 3 by rotating the semiconductor substrate 3.

In FIG. 1, reference numeral 15 designates a washing nozzle for discharging a washing liquid for washing the backside of the semiconductor substrate 3; and reference numeral 4 designates a cup for storing excessive resist and the washing liquid.

Reference numeral 7 designates a dummy dispenser vessel for storing the resist discharged from the resist nozzle 1 in a dummy dispensation step, which will be described later. Reference numeral 8 designates a CCD camera (serving as a video device). The CCD camera 8 is used to visually observe the resist nozzle 1 so as to detect a discharge time, at which the resist nozzle 1 discharges the resist and which is then transmitted to the controller 9.

As shown in FIG. 1, the controller 9 is electrically connected with the spin-motor 6, the CCD camera 8, the air-operate valve 11, and the resist pump 13 so as to control them.

As the controller 9, it is possible to use a personal computer (PC). A program realizing the function of the controller 9 is loaded into a memory of the PC and is executed by a CPU of the PC (not shown).

The controller 9 outputs a dummy discharge signal to the air-operate valve 11 and the resist pump 13, thus discharging a resist. The controller 9 has a calculating function for calculating a delay time corresponding to a time difference between the signaling time for outputting the dummy discharge signal and the discharge time at which the resist is actually discharged. In the present embodiment, the CCD camera 8 is used to detect the discharge time for use in calculation of the delay time by the controller 9.

The controller 9 controls the spin-motor 6 so as to adjust a dry start time in a pre-wet step, which will be described later. Alternatively, the controller 9 outputs the resist discharge signal to the air-operate valve 11 and the resist pump 13 so as to discharge the resist onto the semiconductor substrate 3 at a timing that precedes a dry time in a resist coating step by the delay time.

### 2. RESIST COATING METHOD

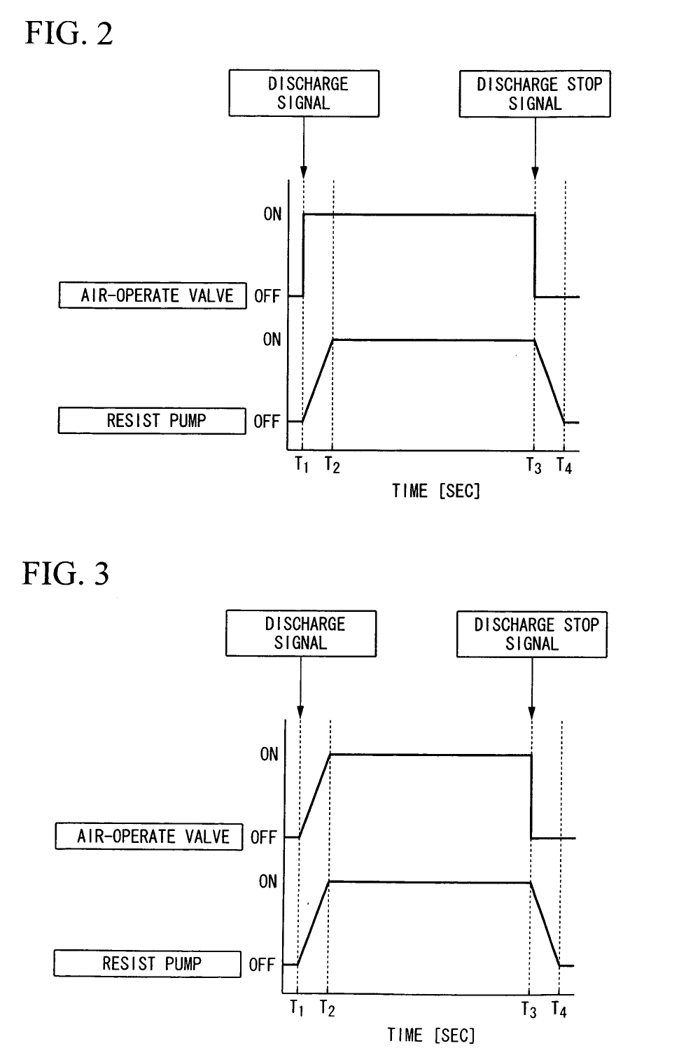

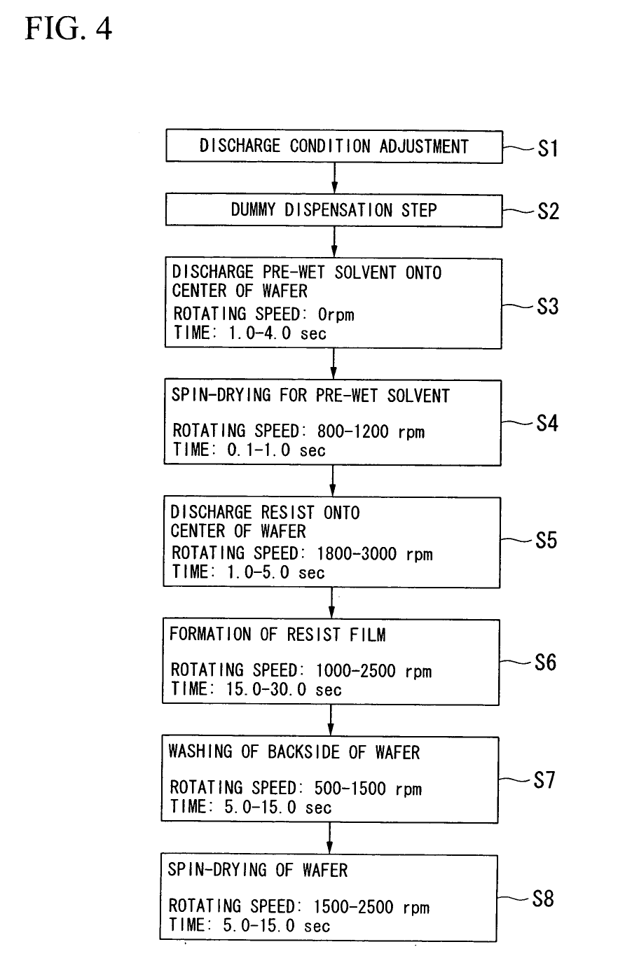

When a resist coating is applied onto the semiconductor substrate 3 by use of the resist coating apparatus of FIG. 1, it is preferable to perform discharge condition adjustment such that the operation timing of the air-operate valve 11 matches the operation timing of the resist pump 13 (see step S1 shown in FIG. 4). FIG. 2 is a graph showing examples of operation timings regarding the air-operate valve 11 and the resist pump 13 before discharge condition adjustment. In FIG. 2, T1 designates the timing when the controller 9 outputs a discharge signal; T2 designates the operation start timing of the resist pump 13; T3 designates the timing when the controller 9 outputs a discharge stop signal; and T4 designates the operation end timing of the resist pump 13.

As shown in FIG. 2, the operation timing of the air-operate valve 11 precedes the operation timing of the resist pump 13, so that the air-operate valve 11 and the resist pump 13 are deviated from each other in terms of the operation timing. In such a condition, the resist nozzle 1 may not always discharge a resist in a good discharge condition. In the case of the example of FIG. 2, the operation start timing of the air-operate valve 11 must be delayed to match the operation start timing T2 of the resist pump 13. That is, as shown in FIG. 3, it is necessary to perform discharge condition adjustment such that the operation start timing of the air-operate valve 11 matches the operation start timing T2 of the resist pump 13, thus realizing a good discharge condition.

FIG. 3 is a graph showing examples of operation timings regarding the air-operate valve 11 and the resist pump 13 after discharge condition adjustment. As shown in FIG. 3, the operation start timing of the air-operate valve 11 matches the operation start timing T2 of the resist pump 13 in the resist coating apparatus after the discharge condition adjustment. In FIG. 3, there remains a deviation between the timing T1 when the controller 9 outputs a discharge signal and the operation start timing of the air-operate valve 11. That is, the discharge condition adjustment may increase the time period between the timing T1 when the controller 9 outputs a discharge signal and the timing at which the resist nozzle 1 actually discharges a resist.

After completion of the discharge condition adjustment, the flow proceeds to step S2 in FIG. 4 so as to perform a dummy dispensation step. In the dummy dispensation step according to the present embodiment, the CCD camera 8 starts observing the resist nozzle 1, then, the nozzle arm 16 operates to move the resist nozzle 1 to a prescribed position just above the dummy dispenser vessel 7. Thereafter, the controller 9 outputs a dummy discharge signal to the air-operate valve 11 and the resist pump 13, which are then activated so that the resist nozzle 1 discharges a resist. When the resist nozzle 1 starts discharging the resist, the CCD camera 8 detects a discharge time at which the resist is discharged and which is then sent to the controller 9. Upon reception of the discharge time from the CCD camera 8, the controller 9 calculates a delay time corresponding to the time difference between the signaling time for outputting the dummy discharge signal and the discharge time.

Next, the resist coating apparatus performs a pre-wet step. In the pre-wet step, the semiconductor substrate 3 is mounted on the spin-chuck 5, then, the nozzle arm 16 moves the solvent nozzle 2 to be positioned just above the center of the semiconductor substrate 3. Then, as shown in step S3 of FIG. 4, the spin-motor 6 stops rotating for a prescribed time period, which may range from 1 second to 4 seconds, for example, while the solvent nozzle 2 discharges a pre-wet solvent. In step S4, the controller 9 controls the spin-motor 6 to rotate so that the semiconductor substrate 3 rotates at a rotating speed ranging from 800 rpm to 1200 rpm for a rotating time ranging from 0.1 seconds to 1.0 seconds, thus performing a coating-drying process (or a spin-drying process). Next, a resist coating step is performed such that the dry time of the pre-wet solvent is normally maintained constant. Before the predetermined dry time of the pre-wet solvent elapses, the nozzle arm 16 moves the resist nozzle 1 to be positioned just above the center of the semiconductor substrate 3 in order to perform the resist coating step.

Subsequently, the resist coating step is performed. In the resist coating step, the spin-motor 6 does not stop rotating the semiconductor substrate 3, which is rotated in the pre-wet step. In step S5, while the semiconductor substrate 3 rotates at a rotating speed ranging from 1800 rpm to 3000 rpm for a rotating time ranging from 1.0 seconds to 5.0 seconds, the resist nozzle 1 discharges the resist in response to a resist discharge signal, which the controller 9 outputs to the air-operate valve 11 and the resist pump 13, at a timing that precedes the predetermined dry time being elapsed in the pre-wet step by the delay time, so that the resist spreads on the overall surface of the semiconductor substrate 3.

The delay time between the signaling time for outputting the resist discharge signal and the timing at which the resist is actually discharged can be regarded as a dry time for a pre-wet solvent additionally introduced. Since the controller 9 outputs the resist discharge signal at a timing that precedes the predetermined dry time being elapsed in the pre-wet step by the delay time, it is possible to normally maintain the constant dry time for the pre-wet solvent.

Next, the flow proceeds to step S6 in which the spin-motor 6 rotates the semiconductor substrate 3 at a rotating speed ranging from 1000 rpm to 2500 rpm for a rotating time ranging from 15.0 seconds to 30.0 seconds, for example, so as to form a resist film having a desired thickness on the semiconductor substrate 3.

Next, the flow proceeds to step S7, in which the washing nozzle 15 discharges a washing liquid while the spin-motor 6 rotates the semiconductor substrate 3 at a rotating speed ranging from 500 rpm to 1500 rpm for a rotating time ranging from 5.0 seconds to 15.0 seconds, for example, whereby the resist adhered to the backside of the semiconductor substrate 3 is washed and removed. In step S8, the semiconductor substrate 3 is dried in a spin-drying step while being rotated by means of the spin-motor 6 at a rotating speed ranging from 1500 rpm to 2500 rpm for a rotating time ranging from 5.0 seconds to 15.0 seconds, for example.

The resist coating method of the present embodiment includes the dummy dispensation step for calculating the delay time by the controller 9, the pre-wet step for applying and drying a pre-wet solvent, and the resist coating step for discharging a resist onto the semiconductor substrate 3 by the resist nozzle 1 in response to a resist discharge signal output from the controller 9 at a timing that precedes the predetermined dry time being elapsed by the delay time, whereby it is possible to maintain a “constant” dry time for the pre-wet solvent irrespective of the delay time between the signaling time for outputting the resist discharge signal and the timing for actually applying the resist onto the semiconductor substrate 3.

When the resist discharge signal for use in the resist coating step is output upon lapse of the predetermined dry time by use of the resist coating apparatus after completion of the discharge condition adjustment, the dry time for the pre-wet solvent may be extended to exceed the prescribed time (i.e., the prescribed dry time required for drying the pre-wet solvent) by the delay time between the signaling time for outputting the resist discharge signal and the timing for actually discharging the resist in the resist coating step. This may degrade the pre-wet effect so as to degrade uniformity in the thickness of the resist film.

In contrast, the resist coating method of the present embodiment is designed such that, the controller 9 outputs the resist discharge signal at a timing that precedes the predetermined dry time being elapsed by the delay time in the resist coating step. This automatically maintains the constant dry time for the pre-wet solvent in a self-adjusting manner.

Therefore, the resist coating method of the present embodiment can stably demonstrate the pre-wet effect when the resist spreads over the semiconductor substrate 3, wherein it is possible to stably maintain uniformity in the thickness of the resist film, and it is possible to reduce dispersion of pre-wet effects among a plurality of resist coating apparatuses.

In addition, the resist coating method of the present embodiment performs the discharge condition adjustment before the dummy dispensation step so as to realize a good discharge condition. For this reason, even when the time difference between the signaling time for outputting the discharge signal and the timing for actually applying the resist onto the semiconductor substrate 3 by the resist nozzle 1 is extended, it is possible to maintain a constant dry time for the pre-wet solvent irrespective of the delay time that is required for the resist to be applied onto the semiconductor substrate 3 after completion of drying of the pre-wet solvent. Hence, it is possible to stably demonstrate the pre-wet effect when the resist spreads over the semiconductor substrate 3.

### 3. WORKING EXAMPLES

### (a) First Example

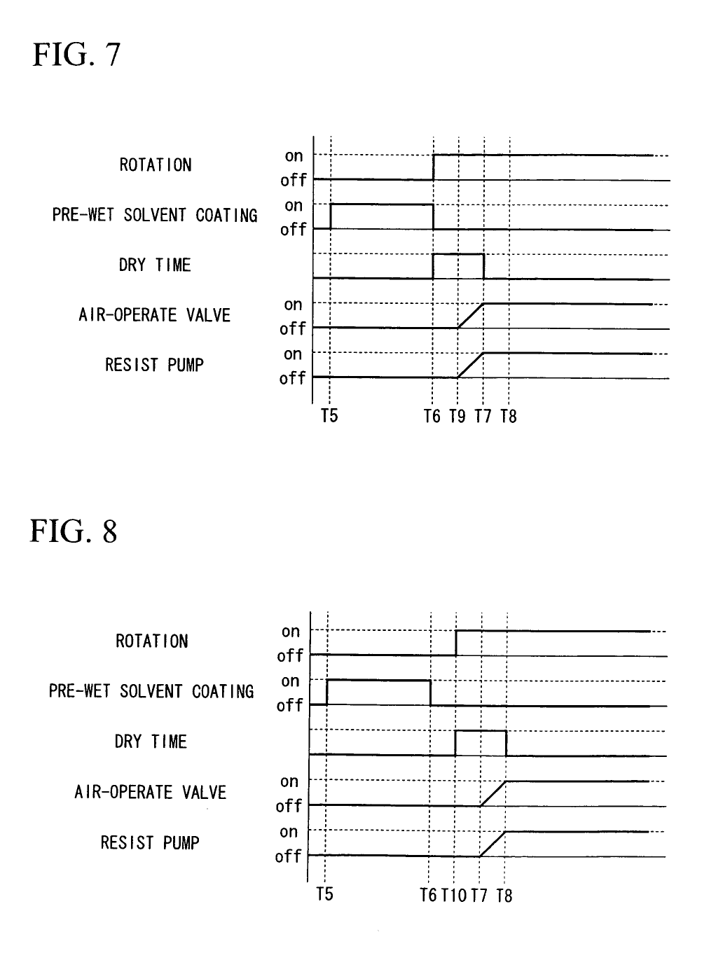

By use of the resist coating apparatus of FIG. 1, a resist is applied onto the semiconductor substrate 3 in accordance with the following method based on the time sequence shown in FIG. 7. The predetermined dry time adapted to the first example is set to 0.1 seconds. The predetermined dry time depends upon resist materials and coating thicknesses; hence, it can be experimentally determined in advance.

First, the discharge condition adjustment is performed so as to match the operation timing of the air-operate valve 11 with the operation timing of the resist pump 13.

Specifically, the operation timing of the air-operate valve 11 is deviated from the operation timing of the resist pump 13 by 0.06 seconds; hence, the operation timing of the air-operate valve 11 is delayed to match the operation timing of the resist pump 13.

After completion of the discharge condition adjustment, the dummy dispensation step is performed. In the dummy dispensation step, the CCD camera 8 is started to observe the resist nozzle 1, wherein the nozzle arm 16 moves the resist nozzle 1 to be positioned just above the dummy dispenser vessel 7. Then, the controller 9 outputs a dummy discharge signal so as to activate the air-operate valve 11 and the resist pump 13, thus making the resist nozzle 1 to discharge a resist onto the semiconductor substrate 3. When the resist nozzle 1 discharges the resist, the CCD camera 8 detects the discharge time of the resist, based on which the controller 9 calculates the delay time. Herein, the delay time is 0.06 seconds in the first example.

Next, the pre-wet step is performed. In the pre-wet step, the semiconductor substrate 3 is mounted on the spin-chuck 5, and the nozzle arm 16 moves the solvent nozzle 2 to be positioned just above the center of the semiconductor substrate 3. At time T5 shown in FIG. 7, the solvent nozzle 2 discharges a pre-wet solvent for two seconds while stopping the spin-motor 6 to rotate. At time T6, the solvent nozzle 2 stops discharging the pre-wet solvent, and at the same time, the controller 9 controls the spin-motor 6 so as to rotate the semiconductor substrate 3 at a rotating speed of 1200 rpm, thus starting a coating-dry process (or a spin-dry process). Before the predetermined dry time (e.g., 0.1 seconds) for the pre-wet solvent elapses, the nozzle arm 16 moves the resist nozzle 1 to be positioned just above the center of the semiconductor substrate (or wafer) 3 in order to prepare for the next resist coating step.

Then, the resist coating step is performed. In the resist coating step, the controller 9 outputs a resist discharge signal at time T9, which is 0.04 seconds after time T6 (for starting the coating-dry process) while the spin-motor 6 does not stop rotating the semiconductor substrate 3 subsequent to the pre-wet step. At time T7, which is a delay time of 0.06 seconds after time T9, the resist is applied to the semiconductor substrate 3 so as to finish the coating-dry process. The resist is applied to the semiconductor substrate 3 under prescribed conditions of a rotating speed of 1800 rpm for a rotating time of 2.0 seconds. The time T9, which is 0.04 seconds after time T6 (for starting the coating-dry process), precedes the predetermined dry time (e.g., 0.1 seconds) being elapsed from time T6 by the delay time of 0.06 seconds. That is, the actual dry time, which is counted from time T6 to time T7, is expressed as “0.04+0.06=0.1” seconds, which precisely matches the predetermined dry time of 0.1 seconds.

Then, the spin-motor 6 rotates the semiconductor substrate 3 at a rotating speed of 1500 rpm for a rotating time of 20 seconds, thus forming a resist film having a desired thickness on the semiconductor substrate 3. The dispersion of uniformity in the thickness of the resist film actually formed ranges within 2.0 nm.

Thereafter, the spin-motor 6 rotates the semiconductor substrate 3 at a rotating speed of 1000 rpm for a rotating time of 5 seconds, wherein the washing nozzle 15 discharges a washing liquid so as to wash and remove the resist attached to the backside of the semiconductor substrate 3. Then, the spin-motor 6 further rotates the semiconductor substrate 3 at a rotating speed of 2000 rpm for a rotating time of 5 seconds, thus drying the semiconductor substrate 3.

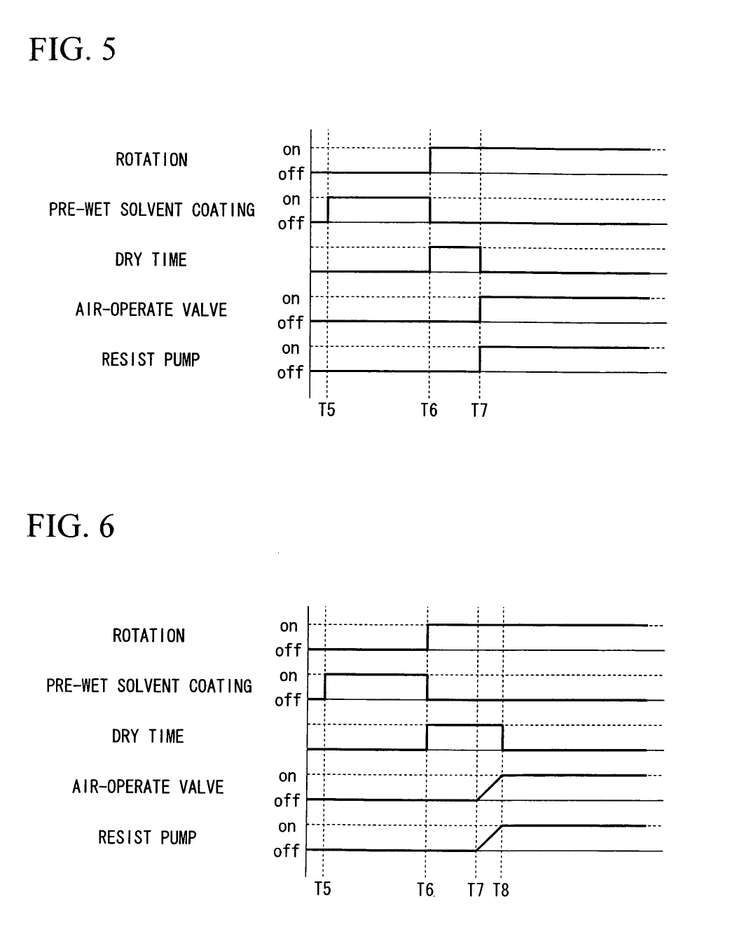

In the first example, with reference to the basic time sequence shown in FIG. 5, the controller 9 outputs a resist discharge signal at a timing that precedes the predetermined dry time being elapsed for the pre-wet solvent by the delay time, which the controller 9 calculates in the dummy dispensation step, thus normally maintaining a constant dry time. The first example can be realized basically in accordance with the basic time sequence of FIG. 5 except that the output timing of the resist discharge signal is shifted forward in the time axis.

### (b) Second Example

A second example is dedicated to a method for normally maintaining a constant dry time by delaying the dry start timing by the delay time. The dummy dispensation step applied to the second example is substantially identical to that of the first example; hence, the description thereof will be omitted. Hence, the second example will be described with respect to the pre-wet step and its following step(s) with reference to the time sequence shown in FIG. 8. In the second example, the predetermined dry time is set to 0.1 seconds, and the delay time is set to 0.06 seconds.

After completion of the dummy dispensation step, the pre-wet step is performed. First, the semiconductor substrate 3 is mounted on the spin-chuck 5, then the nozzle arm 16 moves the solvent nozzle 2 to be positioned just above the semiconductor substrate 3. At time T5 shown in FIG. 8, the solvent nozzle 2 discharges a pre-wet solvent for 2.0 seconds without rotating the spin-motor 6. At time T6, the solvent nozzle 2 stops discharging the pre-wet solvent. At time T10, which is 0.06 seconds after time T6, the controller 9 controls the spin-motor 6 so as to rotate the semiconductor substrate 3 at a rotating speed of 1200 rpm, thus starting the coating-dry process (or spin-dry process). Before the predetermined dry time (e.g., 0.1 seconds) for the pre-wet solvent elapses, the nozzle arm 16 moves the resist nozzle 1 to be positioned just above the center of the semiconductor substrate (or wafer) 3 in order to prepare for the next resist coating step.

Then, the resist coating step is performed. In the resist coating step, the controller 9 outputs a resist discharge signal at time T7, which is 0.04 seconds after time T10 (for starting the coating-dry process) without stopping the spin-motor 6 to rotate the semiconductor substrate 3 subsequently to the pre-wet step. Then, at time T8, which is a delay time of 0.06 seconds after time T7, the dry time is finished so that a resist is applied onto the semiconductor substrate 3. The resist is applied to the semiconductor substrate 3 under prescribed conditions of a rotating speed of 1800 rpm for 2.0 seconds. The time T10, which is 0.04 second elapsed after the time T6 (for starting the coating-dry process), precedes the predetermined dry time (e.g., 0.1 seconds) being elapsed after the time T6 by the delay time of 0.06 seconds. That is, the actual dry time is expressed as “0.04+0.06=1.0” seconds, which precisely matches the predetermined delay time of 0.1 seconds.

Then, the spin-motor 6 rotates the semiconductor substrate 3 at a rotating speed of 1500 rpm for a rotating time of 20 seconds, thus forming a resist film on the semiconductor substrate 3. Herein, the dispersion of the thickness of the resist film ranges within 2.0 nm. The spin-motor 6 further rotates the semiconductor substrate 3 at a rotating speed of 1000 rpm for a rotating time of 5 seconds while the washing nozzle 15 discharges a washing liquid so as to wash and remove the resist attached to the backside of the semiconductor substrate 3. Then, the spin-motor 6 rotates the semiconductor substrate 3 at a rotating speed of 2000 rpm for 5 seconds, thus drying the semiconductor substrate 3.

In the second example, with reference to the basic time sequence of FIG. 5, the controller 9 outputs a rotation signal for the spin-chuck 5 so as to start drying the pre-wet solvent at a timing that is delayed from the timing at which the solvent nozzle 2 stops discharging the pre-wet solvent by the delay time, which the controller 9 calculates in the dummy dispensation step. This makes it possible to normally maintain a constant dry time. The second example can be realized based on the basic time sequence except that the output timing of a dry start signal is delayed.

### (c) Third Example

The third example is basically identical to the first example except that another resist coating apparatus whose delay time is set to 0.02 seconds is used to apply a resist onto the semiconductor substrate 3.

Then, the pre-wet step is performed. In the pre-wet step, the semiconductor substrate 3 is mounted on the spin-chuck 5, wherein the nozzle arm 16 moves the solvent nozzle 2 to be positioned just above the center of the semiconductor substrate 3. Then, at time T5 shown in FIG. 7, the solvent nozzle 2 discharges a pre-wet solvent onto the semiconductor substrate 3 for 2.0 seconds without rotating the spin-motor 6. At time T6, the solvent nozzle 2 stops discharging the pre-wet solvent, and at the same time, the controller 9 controls the spin-motor 6 so as to rotate the semiconductor substrate 3 at a rotating speed of 1200 rpm, thus starting a coating-drying process (or a spin-drying process). In order to prepare for the next resist coating step, the nozzle arm 16 moves the resist nozzle 1 to be positioned just above the center of the semiconductor substrate (or wafer) 3 before the prescribed dry time (e.g., 0.1 second) for the pre-wet solvent elapses.

The third example performs the pre-wet step similar to the first example, then, it performs the resist coating step. In the resist coating step, the controller 9 outputs a resist discharge signal at time T9, which is 0.08 seconds after the time T6 for starting the coating-drying process, without stopping the spin-motor 6 to rotate the semiconductor substrate 3 subsequently to the pre-wet step. At time T7, which is delayed from the time T9 by the delay time of 0.02 seconds, the resist is applied to the semiconductor substrate 3 and is then dried. The resist is applied to the semiconductor substrate 2 under prescribed conditions of a rotating speed of 1800 rpm for a rotating time of 2.0 seconds. The time T9, which is 0.08 seconds after the time T6 for starting the coating-drying process, precedes the predetermined dry time (e.g., 0.1 seconds) being elapsed by the delay time of 0.02 seconds.

That is, the actual delay time is calculated as “0.08+0.02−0.1” seconds, which precisely matches the predetermined dry time of 0.1 seconds. Thereafter, the foregoing step described in the first embodiment is performed so as to form a resist film on the semiconductor substrate 3. The dispersion in the thickness of the resist film which is actually formed on the semiconductor substrate 3 in accordance with the third example ranges within 2.0 nm.

### (d) First Comparative Example

The aforementioned resist coating apparatus used in the first example is used to perform discharge condition adjustment similar to the first example. After completion of the discharge condition adjustment, a resist film is formed on the semiconductor substrate 3 similar to the first example with reference to the time sequence shown in FIG. 6 except that the signaling time for outputting the resist discharge signal is set to a timing at which the predetermined dry time for the pre-wet solvent elapses. In the first comparative example similar to the first example, the predetermined dry time for the pre-wet solvent is set to 0.1 seconds, and the delay time is set to 0.06 seconds. This indicates that the actual dry time becomes 0.16 seconds, which is calculated by adding the delay time to the predetermined dry time, that is, the coating-drying process is performed for a longer time by the delay time. The dispersion in the thickness of the resist film, which is formed on the semiconductor substrate 3 in accordance with the first comparative example, ranges within 3.0 nm.

### (e) Second Comparative Example

The aforementioned resist coating apparatus used in the third example is used to perform the resist coating step on the semiconductor substrate 3 in accordance with the aforementioned method described in the first comparative example. In the second comparative example, which is identical to the third example, the predetermined dry time is set to 0.1 seconds, and the delay time is set to 0.02 seconds. That is, the actual dry time becomes 0.12 seconds, which is calculated by adding the delay time to the predetermined dry time; hence, the coating-drying process is performed for a longer time by the delay time. The dispersion of the thickness of the resist film which is formed on the semiconductor substrate 3 in accordance with the second comparative example ranges within 2.6 nm.

### (f) Conclusion

The first, second, and third examples according to the present invention prove that the actual dry time for the pre-wet solvent can be maintained constant irrespective of the delay time between the signaling time for outputting the resist discharge signal and the timing for actually applying the resist onto the semiconductor substrate 3. That is, these examples clearly show that the present invention can uniform the thickness of a resist film formed on the semiconductor substrate 3.

In contrast, in the first and second comparative examples, the actual dry time for the pre-wet solvent may vary dependent upon the delay time between the signaling time for outputting the resist discharge signal and the timing for actually applying the resist onto the semiconductor substrate 3. This degrades pre-wet effects; hence, uniformity in the thickness of a resist film formed on the semiconductor substrate 3 is degraded in the first and second comparative examples compared with the first, second, and third examples of the present invention.

### 4. INDUSTRIAL APPLICABILITY

As described above, the present invention is applicable to any types of semiconductor devices, which are produced by performing resist coating steps after pre-wet solvents are applied to semiconductor substrates.

Lastly, the present invention is not necessarily limited to the preferred embodiment and its working examples, which can be further modified in a variety of ways within the scope of the invention defined by the appended claims.

What is claimed is:

1. A resist coating method comprising:
a dummy dispensation step for discharging a resist onto a semiconductor substrate in response to a dummy discharge signal and for calculating a delay time between a timing for issuing the dummy discharge signal and a timing for discharging the resist;
a pre-wet step for applying a pre-wet solvent onto the semiconductor substrate and for performing a dry process on the pre-wet solvent for a predetermined dry time; and
a resist coating step, which is performed subsequent to the pre-wet step, for discharging the resist in response to a resist discharge signal so as to apply the resist onto the semiconductor substrate,
wherein the resist is applied to the semiconductor substrate in the resist coating step in such a way that the resist discharge signal is output at a timing that precedes the predetermined dry time being elapsed by the delay time, thus normally maintaining the predetermined delay time constant.

2. A resist coating method according to claim 1, wherein the dry process is started upon completion of application of the pre-wet solvent in the pre-wet step.

3. A resist coating method according to claim 1, wherein a plurality of resist coating apparatuses are controlled in such a way that the predetermined dry time of the pre-wet solvent is normally maintained constant therebetween, thus reducing a dispersion regarding a thickness of a resist film formed on the semiconductor substrate therebetween.

4. A resist coating method according to claim 1, wherein the dry process of the pre-wet step is started at a timing that is delayed from a timing of completion of application of the pre-wet solvent by the delay time.

5. A resist coating method according to claim 1, wherein the delay time applied to the timing for starting the dry process in the pre-wet step is canceled by the delay time that is calculated between the timing for outputting the resist discharge signal and the timing for actually discharging the resist onto the semiconductor substrate, thus normally maintaining the predetermined dry time of the pre-wet solvent constant.

6. A resist coating method according to claim 1, wherein a plurality of resist coating apparatuses are controlled in such a way that the delay time applied to the timing for starting the dry process in the pre-wet step is canceled by the dry time delay time that is calculated between the timing for outputting the resist discharge signal and the timing for actually discharging the resist onto the semiconductor substrate, thus normally maintaining the predetermined dry time of the pre-wet solvent constant therebetween, and thus reducing a dispersion regarding a thickness of a resist film formed on the semiconductor substrate therebetween.

7. A resist coating method according to claim 1, wherein a video device is used to detect the timing for actually discharging the resist, based on which the delay time is calculated.

8. A resist coating method according to claim 1, wherein the resist coating step is realized using an air-operate valve and a resist pump, and wherein discharge condition adjustment is performed between an operation timing of the air-operate valve and an operation timing of the resist pump before the dummy dispensation step.

9. A resist coating apparatus comprising:
a pre-wet means for applying a pre-wet solvent onto a semiconductor substrate and for performing a dry process on the pre-wet solvent for a predetermined dry time;
a resist coating means for discharging a resist onto the semiconductor substrate; and
a controller for outputting a dummy discharge signal to the resist coating means to start discharging the resist, for calculating a delay time corresponding to a time difference between a timing for outputting the dummy discharge signal and a timing for actually discharging the resist, and for outputting a resist discharge signal to the resist coating means at a timing that precedes the predetermined dry time being elapsed by the delay time, thus discharging the resist to be applied onto the semiconductor substrate.

10. A resist coating apparatus according to claim 9, wherein the controller is equipped with a video device for detecting the timing for actually discharging the resist, based on which the controller calculates the delay time.
